(19) United States
(12) Patent Application Publication
(10) Pub. No.: US 2022/0367353 A1
(43) Pub. Date: Nov. 17, 2022

(54) SEMICONDUCTOR DEVICES AND METHODS OF MANUFACTURING

(71) Applicant: TAIWAN SEMICONDUCTOR MANUFACTURING COMPANY, LTD., Hsinchu (TW)

(72) Inventors: Jia-Chuan YOU, Dayuan Township (TW); Chia-Hao CHANG, Hsinchu City (TW); Li-Zhen YU, New Taipei City (TW); Lin-Yu HUANG, Hsinchu (TW)

(21) Appl. No.: 17/491,179

(22) Filed: Sep. 30, 2021

Related U.S. Application Data
(60) Provisional application No. 63/188,972, filed on May 14, 2021.

(51) Int. Cl. H01L 23/528; H01L 29/45; H01L 29/417; H01L 21/768

(52) U.S. Cl. CPC H01L 23/5283; H01L 29/456; H01L 29/41775; H01L 21/76802; H01L 21/76843

(57) ABSTRACT

In forming a semiconductor structure, a two-step breakthrough etching method is employed in which a glue layer and dielectric liner are broken-through sequentially in order to successfully gain device performance and avoid drain or gate metal damage.

### CROSS-REFERENCE TO RELATED APPLICATIONS

This application claims priority under 35 U.S.C. § 119(e) to U.S. Provisional Patent Application Ser. No. 63/188,972 entitled “TWO STEP BREAKTHROUGH METHOD FOR IMPROVING DEVICE PERFORMANCE” filed on May 14, 2021, the entirety of which is hereby incorporated by reference.

### BACKGROUND

Integrated circuits (ICs) are often designed with active devices, such as transistors, resistors and capacitors connected by conductive traces, such as metal lines and polysilicon lines, to form circuits. The active devices in ICs are formed by a photolithographic process that includes the use of photoresists, photolithographic masks (masks), specialized light sources and various etchants. Increasingly dense ICs have numerous benefits in terms of speed, functionality and cost, but cause increasingly difficult design and fabrication problems. With a decrease of dimensions of semiconductor devices, low resistance contacts have been widely utilized for fabricating, e.g., source/drain contacts arranged close to gate structures in a field effect transistor (FET).

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a cross-sectional view of a manufactured semiconductor device in accordance with some embodiments.

FIG. 2, FIG. 3, FIG. 4, FIG. 5, FIG. 5A, FIG. 6, FIG. 7, FIG. 8 and FIG. 9 show cross-sectional views of various stages of a sequential fabrication process of a semiconductor device according to some embodiments.

FIG. 9A shows a detailed cross sectional view of a drain contact in accordance with some embodiments.

FIG. 9B shows a detailed cross sectional view of a gate contact in accordance with some embodiments.

FIG. 10 shows a second semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows includes embodiments in which the first and second features are formed in direct contact, and also includes embodiments in which additional features are formed between the first and second features, such that the first and second features are not in direct contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element or feature's relationship to another element(s) or feature(s) as illustrated in the Figures. The spatially relative terms are intended to encompass different orientations of the device in use or operation in addition to the orientation depicted in the figures. The apparatus/device may be otherwise oriented (rotated 90 degrees or at other orientations) and the spatially relative descriptors used herein may likewise be interpreted accordingly. In addition, the term “made of” may mean either “comprising” or “consisting of” In the present disclosure, a phrase “one of A, B and C” means “A, B and/or C” (A, B, C, A and B, A and C, B and C, or A, B and C), and does not mean one element from A, one element from B and one element from C, unless otherwise described.

The present disclosure describes three-dimensional semiconductor structures shown in cross-section. In some embodiments, the semiconductor substrate is a semiconductor wafer, such as a silicon wafer or other type of wafer to be patterned. Certain embodiments describe the exemplary manufacturing process of one or more semiconductor devices. The semiconductor device may be formed on bulk silicon substrates in certain embodiments. The semiconductor device may be formed on silicon-on-insulator (SOI) substrates in alternate embodiments. Also, in accordance with some embodiments, the silicon substrate may include other conductive layers or other semiconductor device elements, such as transistors, diodes and the like that may not be explicitly shown. Accordingly, the embodiments described herein are not limited to the structures as shown. In the present disclosure a “source/drain” refers to a source, a drain or both source and drain, and a source and a drain are interchangeable. In the present disclosure, the metal materials (e.g., W, Ru, etc.) have a purity more than 99% and may contain unavoidable impurities.

As illustrated in the Figures and described herein, in various embodiments, the semiconductor device 100 is a FET such as a planar FET or a FinFET. In other implementations, the semiconductor device 100 is one or more other types of devices such as a vertical gate all around (VGAA) FET, a horizontal gate all around (HGAA) FET, a bipolar junction transistor (BJT), a diode, a capacitor, an inductor, a resistor, and the like. In embodiments involving planar FETs and/or FinFETs, gates are formed on active areas of a semiconductor substrate. In some embodiments, the active areas are a portion at a top surface of the semiconductor substrate 101 delineated by isolation regions. In some FinFET embodiments, the substrate 101 includes a fin structure. In some FinFET embodiments, the active areas are three-dimensional fins protruding between isolation regions on the semiconductor substrate. In various embodiments, the semiconductor substrate 101 is a bulk semiconductor substrate, a semiconductor-on-insulator (SOI) substrate, or another substrate. In various embodiments, the semiconductor material of the semiconductor substrate is doped or un-doped, such as with a P-type or an N-type dopant. Other substrates, such as a multi-layered or gradient substrate may also be used in various embodiments. In some embodiments, the semiconductor material of the semiconductor substrate 101 may include an elemental semiconductor like silicon (Si) (e.g., crystalline silicon, like Si<100> or Si<111>) and germanium (Ge); or a compound semiconductor including silicon carbide (SiₓC_{y}), gallium arsenide (GaₓAs_{y}), gallium phosphide (GaₓP_{y}), indium phosphide (InₓP_{y}), indium arsenide (InₓAs_{y}), and/or indium antimonide (InₓSb_{y}); or an alloy semiconductor including SiₓGe_{y}, GaₓAs_{y}P_{z}, aluminum indium arsenide (AlₓIn_{y}As_{z}), AlₓGa_{y}As_{z}, GaₓIn_{y}As_{z}, GaₓIn_{y}P_{z}, Ga_{w}InₓAs_{y}P_{z} or a combination thereof. The various layers of the semiconductor device 100 combine to form various IC features such as an active region of a transistor, a gate electrode, a source, a drain, metal lines, vias (i.e., of an interlayer interconnection), and openings for bonding pads, to be formed in a semiconductor substrate 101 (such as a silicon wafer) and various material layers disposed on the semiconductor substrate 101.

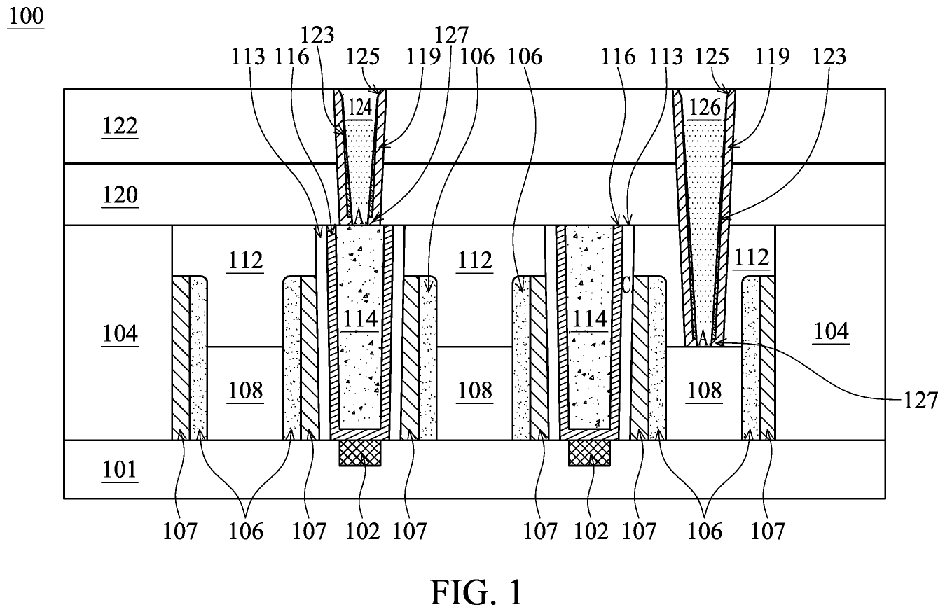

As shown in FIG. 1, the semiconductor device 100 includes a silicide layer 102 disposed or formed within a top surface of a substrate 101. Metallic silicides are used as contact materials on source/drains and gates in a variety of metal oxide semiconductor (MOS) structures, such as transistors or memories. They are fabricated by a reaction between a metal or a metallic alloy thin film and the substrate 101 in various embodiments. In various embodiments, the silicide material of the silicide layer 102 is at least one of nickel silicide (NiₓSi_{y}), titanium silicide (TiₓSi_{y}), tungsten silicide (WₓSi_{y}), cobalt silicide (CoₓSi_{y}), ruthenium silicide (RuₓSi_{y}). In some embodiments, the silicide layer 102 may be composed of sodium silicide (NaₓSi_{y}), magnesium silicide (MgₓSi_{y}), platinum silicide (PtₓSi_{y}), molybdenum silicide (MbₓSi_{y}), or any material of like properties. A thickness of the silicide layer 102 is between about 1 and about 20 nanometers (nm) in various embodiments, such as between about 5 nm and about 10 nm. In some embodiments, a top surface of the silicide layer 102 is substantially even with the top surface of the substrate 100. In other embodiments, a portion of the silicide layer 102 extends above a top surface of the substrate 101. In some embodiments, the silicide layer 102 is formed on an epitaxial semiconductor layer of the source/drains.

In various embodiments, a first spacer 106 is disposed on a sidewall of the gate electrode between regions of the dielectric layer 104 to form a gate structure or the like. In some embodiments, the first spacer 106 protects against electric shorting between the gate structure formed therein and any adjacent gates or drains. In some embodiments, in the gate structure, the first spacer 106 is a single-layer structure. In alternate embodiments, the first spacer 106 is a multiple-layer structure, including one or more oxide layers and one or more nitride layers, such as an oxide-nitride-oxide (ONO) arrangement. In some embodiments, the material of the first spacer 106 includes SiO₂, silicon nitride, SiₓO_{y}N_{z}, SiₓC_{y}N_{z}, Si_{w}OₓC_{y}N_{z} or other suitable material. In some embodiments, the first spacer 106 has a vertical thickness in the range of about 1 to about 25 nm, such as about 4 nm to about 12 nm. In some embodiments, a cross-section view of the sidewalls of the first spacer 106 is substantially rectangular. In some embodiments, the method of forming the first spacer 106 may include a deposition process followed by an etching process. In such embodiments, the deposition process may include atomic layer deposition (ALD), molecular beam deposition (MBD), CVD, PVD, flowable chemical vapor deposition (FCVD), or a combination thereof. In such embodiments, the etching process may include an anisotropic etching process or other suitable process. One skilled in the art will readily appreciate that each of the two first spacers 106 shown in cross-section on either side of a gate metal layer 108 are merely artifacts of the cross-sectional view depicted in the Figures. In various embodiments, each such pair of first spacers 106 are actually opposing vertical or near-vertical edges of a continuous single first spacer 106 which surrounds and encloses the gate metal layer 108 and other layers in the three-dimensional semiconductor device 100. Similar artifacts appear for other features of the semiconductor device 100 described herein, as will be readily appreciated by one of ordinary skill in the art.

In various embodiments, a second spacer 107 is disposed between the first spacers 106 and the dielectric layer 104 to provide additional electrical isolation of the gate structures. In some embodiments, the method of forming the second spacer 107 may include a deposition process followed by an etching process. In such embodiments, the deposition process may include ALD, molecular beam deposition (MBD), CVD, PVD, FCVD, or a combination thereof. In such embodiments, the etching process may include an anisotropic etching process or other suitable process. In some embodiments, the material used to form the second spacer 107 is at least one of SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZnₓO_{y}, SiₓO_{y}C_{z}, HfₓO_{y}, LaₓO_{y}, AlₓO_{y}, Si_{w}OₓC_{y}N_{z}, AlₓO_{y}N_{z}, YₓO_{y}, and TaₓC_{y}N_{z}. In some embodiments, a thickness of the second spacer 107 is between about 1 nm and about 30 nm, such as between about 5 nm and about 20 nm. In some embodiments, the second spacer 107 is omitted from the gate structure of the semiconductor device 100, according to design requirements. In various embodiments, a cross-section of the second spacer 107 is coextensive with the neighboring first spacer 106, both of which extend above a gate metal layer 108 on the substrate 101.

In various embodiments, the gate metal (MG) layer 108 is deposited within the first spacer 106. In some embodiments, the thickness of the gate metal layer 108 extends from the bottom of the dielectric layer 104 towards a top of the first spacer 106. In some embodiments, the gate metal layer 108 does not extend to or beyond the top surface of the first spacer 106 in order to allow room for other gate features, so as to form a gate structure of a FinFET, another type of transistor or the like. In some embodiments, a cross-section of the gate metal layer 108 is substantially square. In some embodiments, a cross-sectional view of the gate metal layer 108 is substantially rectangular or trapezoidal. In some embodiments, a material of the gate metal layer 108 includes TiₓAl_{y}, TiₓAl_{y}N_{z}, TaₓC_{y}N_{z}, TiₓN_{y}, WₓN_{y}, tungsten, combinations thereof, or any other suitable conductive material. In some embodiments, the gate metal layer 108 may be formed by performing one or more of ALD, PVD, CVD, or other suitable process. In some embodiments, the completed gate structure may be a buried gate or dummy gate according to design requirements. In other embodiments, the completed gate structure may be a gate contact pad that allows electrical conduction under various operating conditions. In various embodiments, more than two gate structures as shown are formed in the semiconductor device, such as 2, 4 or more gate structures. In some embodiments, various gate structures formed in the semiconductor device 100 may have the same or dissimilar construction according to design requirements. In some embodiments, a height of the gate metal layer 108 ranges between about 14 nm and about 22 nm, such as between about 15 nm and about 20 nm.

In various embodiments, the gate structures can be applied in P-channel field-effect devices, N-channel field-effect devices, or both based on design requirements. Each gate structure may include a single-layer or multi-layer configurations (not shown), including one or more of an interfacial layer, a high-k layer, a work function layer, a blocking layer, an adhesion layer, and a metal filling layer. In various embodiments, the material used to form the gate structures include one or more of titanium, silver, aluminum, HfₓO_{y}, AlₓTi_{y}C_{z}, AlₓTi_{y}O_{z}, AlₓTi_{y}N_{z}, AlₓTi_{y}C_{z}, AlₓTi_{y}O_{z}, TiₓAl_{y}N_{z}, TaₓC_{y}, TaₓC_{y}N_{z}, TaₓSi_{y}N_{z}, WₓN_{y}, TiₓN_{y}, TaₓN_{y}, manganese, zirconium (Zr), ruthenium, moybdenum, copper, tungsten, or any other suitable material.

In various embodiments, a dielectric layer 104, such as a first interlayer dielectric (ILD), is disposed between gate structures formed on the substrate 101. In some embodiments, a dielectric material of the dielectric layer 104 is an oxide, a silicon nitride (SiₓN_{y}), a silicon oxynitride (SiₓO_{y}N_{z}) or any other suitable dielectric material. In other embodiments, a dielectric material of the dielectric layer 104 is silicon dioxide (SiO₂), Si_{w}OₓC_{y}H_{z}, borophosphosilicate glass (BPSG), spin-on glass (SOG), undoped silicate glass (USG), fluorinated silicate glass (FSG), high-density plasma (HDP) oxide, fluorine-doped silicon oxide, carbon-doped silicon oxide, porous silicon oxide, porous carbon-doped silicon oxide, organic polymers, silicone based polymers, or is made from tetraethyl orthosilicate (TEOS) or plasma-enhanced TEOS (PETEOS). In some embodiments, the dielectric layer 104 includes a low-k dielectric material having a dielectric constant (k) that is smaller than a dielectric constant of SiO₂ (which is approximately 4). In some embodiments, the low-k dielectric material is associated with a dielectric constant (k) less than about 3.9. In some embodiments, k is between about 1.5 and about 2.8. In various embodiments, the dielectric layer 104 is formed by atomic layer deposition (ALD), chemical vapor deposition (CVD), physical vapor deposition (PVD), or combinations thereof.

In some embodiments, a cap layer (not shown) is next formed over the gate metal layer 108 within the walls of the first spacer 106. In various embodiments, the cap layer provides conductivity to and protects the underlying gate metal layer 108. In some embodiments, a material of the cap layer includes aluminum (Al), tungsten (W), copper (Cu), combinations thereof or any other suitable conductive material.

In various embodiments, a gate helmet layer 112 is next disposed over the gate metal layer 108 or the cap layer. In various embodiments, the gate helmet layer 112 provides a protection or isolation for the underlying cap layer, if provided, and gate metal layer 108 to form a completed gate structure, in accordance with design requirements. In some embodiments, the gate helmet layer 112 is a self-aligned contact (SAC) formed over the cap layer. In various embodiments, the gate helmet layer 112 is configured to protect underlying features of the gate structure during subsequent processing steps. In some embodiments, the gate helmet layer 112 is a sacrificial layer for forming self-aligned contacts. In some embodiments, a material used to form the gate helmet layer 112 are at least one of: SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZrₓO_{y}, SiₓO_{y}C_{z}, HfₓO_{y}, LaₓO_{y}, AlₓO_{y}, Si_{w}OₓC_{y}N_{z}, AlₓO_{y}N_{z}, YₓO_{y}, TaₓC_{y}N_{z} and SiₓO_{y}. In some embodiments, the gate helmet layer 112 is T-shaped, and the first spacers 106 and the second spacer 107 extend from a bottom of the dielectric layer 104 to a bottom surface of the arms of the “T” formed by the gate helmet layer 112. In some embodiments, the first spacer 106 and the second spacer 107 extend beyond the bottom surface of the bottom portion of gate helmet layer 112 but do not extend beyond the bottom surface of the top portion of the gate helmet layer 112. In some embodiments, a thickness of a bottom portion of the “T” of the gate helmet layer 112 is between about 1 nm and about 30 nm, such as between about 10 nm and about 20 nm. In some embodiments, the bottom portion of the gate helmet layer 112 is omitted entirely according to design requirements. In some embodiments, a thickness of a top portion of the “T” of the gate helmet layer 112 is between about 1 nm and about 30 nm, such as between about 10 nm and about 20 nm. In some embodiments, the bottom portion of the gate helmet layer 112 is omitted entirely according to design requirements, however, in various embodiments, at least one of the bottom portion and the top portion of the gate helmet layer 112 is present in the gate structure. Three exemplary gate structures are shown in FIG. 1 between, and on either side of, two exemplary drain structures as described below.

In various embodiments, a drain liner layer 113 made of an insulating material is disposed on a sidewall of a contact hole formed in the dielectric layer 104 to provide additional electrical isolation of the drain structures formed therein. In some embodiments, the method of forming the drain liner layer 113 may include a deposition process followed by an etching process. In such embodiments, the deposition process may include ALD, molecular beam deposition (MBD), CVD, PVD, FCVD, or a combination thereof. In such embodiments, the etching process may include an anisotropic etching process or other suitable process. In some embodiments, the material used to form the drain liner layer 113 is at least one of SiₓN_{y}, ZrₓSi_{y}, SiₓC_{y}N_{z}, ZrₓAl_{y}O_{z}, TlₓO_{y}, TaₓO_{y}, ZrₓO_{y}, LaₓO_{y}, ZrₓN_{y}, SiₓC_{y}, ZₓO_{y}, SiₓO_{y}C_{z}, HfₓO_{y}, LaₓO_{y}, AlₓO_{y}, Si_{w}OₓC_{y}N_{z}, AlₓO_{y}N_{z}, YₓO_{y}, and TaₓC_{y}N_{z}. In some embodiments, a thickness of the drain liner layer 113 is between about 1 nm and about 30 nm, such as between about 5 nm and about 20 nm.

In various embodiments, a drain glue layer 116 made of a conductive material is deposited along an inner surface of the drain liner layer 113 and along a portion of a top surfaces of the underlying silicide layer 102 and the substrate 101 (e.g., a part of fin) within the drain structure. In some embodiments, the drain glue layer 116 enhances side wall adhesion of drain metal layer 114. In some embodiments, the drain glue layer 116 is a single layer. In such embodiments, the material of the drain glue layer 116 is at least one of cobalt, ruthenium, tantalum nitride (TaₓN_{y}), titanium silicide (TiₓSi_{y}) and titanium nitride (TiₓN_{y}). In some embodiments, the glue layer comprises two or more layers. In such embodiments, the material of the drain glue layer 116 is a TiₓSi_{y} layer with a TiₓN_{y} layer, or a TiₓSi_{y} layer with a TaₓN_{y} layer. In some embodiments, a thickness of the drain glue layer 116 at the sidewall is between about 0.2 nm and about 5 nm, such as between about 1 nm and about 3 nm. In some embodiments, a thickness of the drain glue layer 116 disposed on the top surface of the silicide layer 102 and a surrounding portion of the substrate 101 is between about 0.2 nm and about 5 nm, such as between about 1 nm and about 3 nm.

In various embodiments, the drain structure includes a drain metal layer 114 that is deposited over the drain glue layer 116 by PVD, CVD or the like. In various embodiments, the material used to form the drain metal layer 114 is a metal such as: copper, tungsten, ruthenium, cobalt, and TiₓN_{y}. In various embodiments, a cross-section of the drain metal layer 114 is substantially square, rectangular or trapezoidal. In some embodiments, a length of the top surface of the drain metal layer 114 is between about 1 nm to about 80 nm, such as between about 2 nm and about 40 nm. In other embodiments, a length of the top surface of the drain metal layer 114 is between about 2 nm and about 40 nm. In some embodiments, a length of the bottom surface of the drain metal layer 114 is between about 1 nm to about 80 nm, such as between about 2 nm and about 40 nm. In some embodiments, a thickness of the drain metal layer 114 is between about 1 nm and about 90 nm, such as between about 20 nm and about 50 nm.

In various embodiments, the drain metal layer 114 is deposited on top of the glue layer 116 by PVD or CVD to complete the drain structure of the semiconductor device 100. In various embodiments, a chemical mechanical polishing (CMP) process or the like is employed to smooth and make substantially flat the top surface of the dielectric layer 104, the top surface of the gate helmet layer 112 and the top surface of the drain metal layer 114 in order to form a continuous top transistor surface for further processing of the semiconductor device 100.

In various embodiments, a first etch stop layer (ESL) 120 is deposited over the continuous top transistor surface. In some embodiments, the material for the first etch stop layer 120 includes one or more deposited layers of insulating material such as SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZnₓO_{y}, SiₓO_{y}C_{z}, HfₓO_{y}, AlₓO_{y}, Si_{w}OₓC_{y}N_{z}, AlₓO_{y}N_{z}, YₓO_{y}, TaₓC_{y}N_{z}, SiₓO_{y}, SiₓO_{y}N_{z}, or the like. In some embodiments, the first etch stop layer 120 may be formed by depositing and annealing a metal oxide material, which includes Hf, HfO₂, or Al. In some embodiments, the first etch stop layer 120 is formed using a suitable process such as ALD, CVD, PVD, molecular beam epitaxy (MBE), spin-on, or combinations thereof. In some embodiments, the first ESL 120 has a thickness in a range from about 1 to about 30 nm, such as about 3 nm to about 10 nm.

In various embodiments, a second ILD layer 122 is next disposed over the first ESL 120. In some embodiments, the material of the second ILD layer 122 is different from the material of the first ESL 120. In some embodiments, the second ILD layer 122 has a different etch selectivity from the first spacer 106 and the first ESL 120. In some embodiments, the material of the second ILD layer 122 includes SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZnₓO_{y}, SiₓO_{y}C_{z}, HfₓO_{y}, AlₓO_{y}, Si_{w}OₓC_{y}N_{z}, AlₓO_{y}N_{z}, YₓO_{y}, TaₓC_{y}N_{z}, SiₓO_{y}, SiₓO_{y}N_{z}, or other suitable material. In some embodiments, the method of forming the second ILD layer 122 includes a deposition process followed by a smoothing or planarization of the top layer. In some embodiments, the deposition process includes ALD, molecular beam deposition (MBD), CVD, PVD, FCVD, or a combination thereof. The planarization process may include a CMP process, an etch process, or other suitable process. In some embodiments, the second ILD layer 122 is a single-layer structure. In some alternative embodiments, the second ILD layer 122 is a multi-layer structure having a hard mask layer as an uppermost layer. In various embodiments, the second ILD layer 122 is used to electrically separate closely-spaced interconnect lines arranged in several levels (multilevel metallization) as employed in advanced integrated circuit designs.

In various embodiments, the first ESL 120 and the second ILD layer 122 are next etched to form an opening (drain via) there-through to expose a portion of the drain metal layer 114 and one or more additional openings (gate vias) to expose the gate metal layer 108 in accordance with design requirements. In various embodiments, the drain via (VD) has a sidewall that is within 0 and 20 degrees of vertical. In various embodiments, the drain via extends through the first ESL 120 and the second ILD layer 122 to reach the top horizontal surface of the drain metal layer 114. In various embodiments, the gate via (VG) has a sidewall that is within 0 and 20 degrees of vertical. In some embodiments, the gate via extends through the first ESL 120, the second ILD layer 122, and the gate helmet layer 112 to reach the horizontal surface of the underlying gate metal layer 108.

In various embodiments, a liner layer 119 made of an insulating material is next deposited over the top surfaces of the second ILD layer 122, along the sidewalls of the gate via and drain via, and over the exposed portions of the top horizontal surface of the drain metal layer 114 and the gate metal layer 108. In some embodiments, the material used to form the liner layer 119 is at least one of SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZnₓO_{y}, SiₓO_{y}C_{z}, HfₓO_{y}, LaₓO_{y}, AlₓO_{y}, Si_{w}OₓC_{y}N_{z}, AlₓO_{y}N_{z}, YₓO_{y}, and TaₓC_{y}N_{z}. In some embodiments, a thickness of the liner layer 119 is between about 1 nm and about 30 nm, such as between about 3 nm and about 10 nm. In some embodiments, the liner layer 119 has a tapered end 125 at or near a top of the sidewall of the drain via and/or the gate via after processing. In some embodiments, the liner layer 119 is deposited along the sidewall of the drain via, over the horizontal surface of the drain metal layer 114, along a sidewall of the gate via, and over the horizontal surface of the gate metal layer 108.

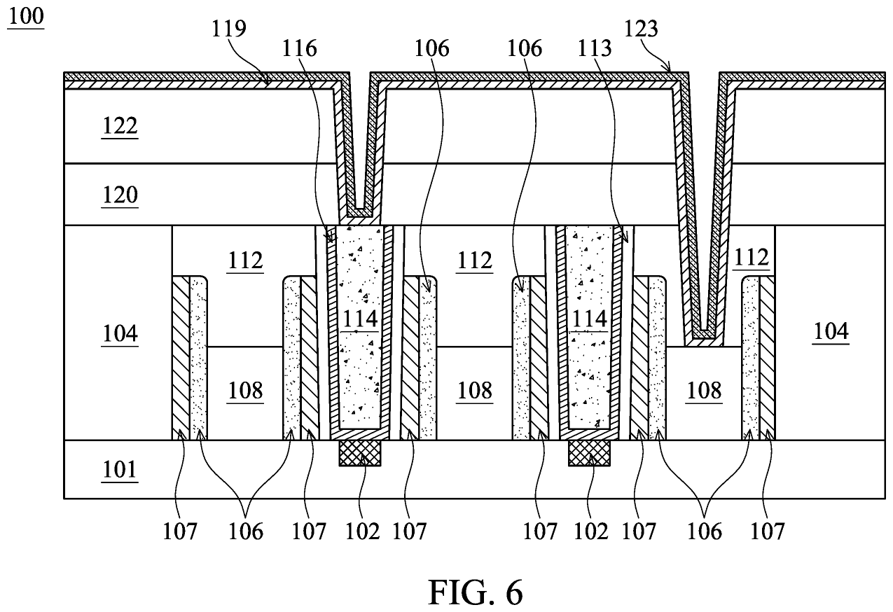

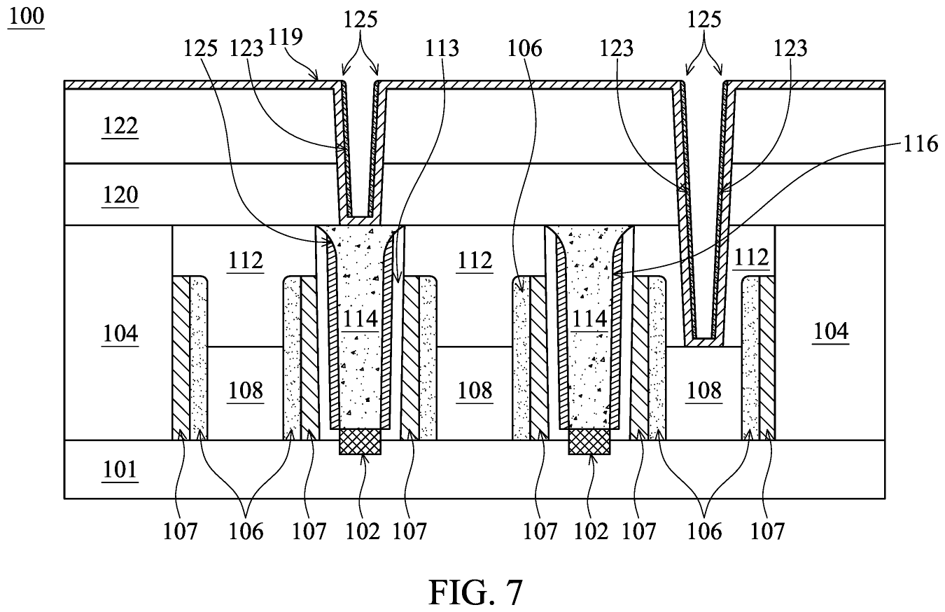

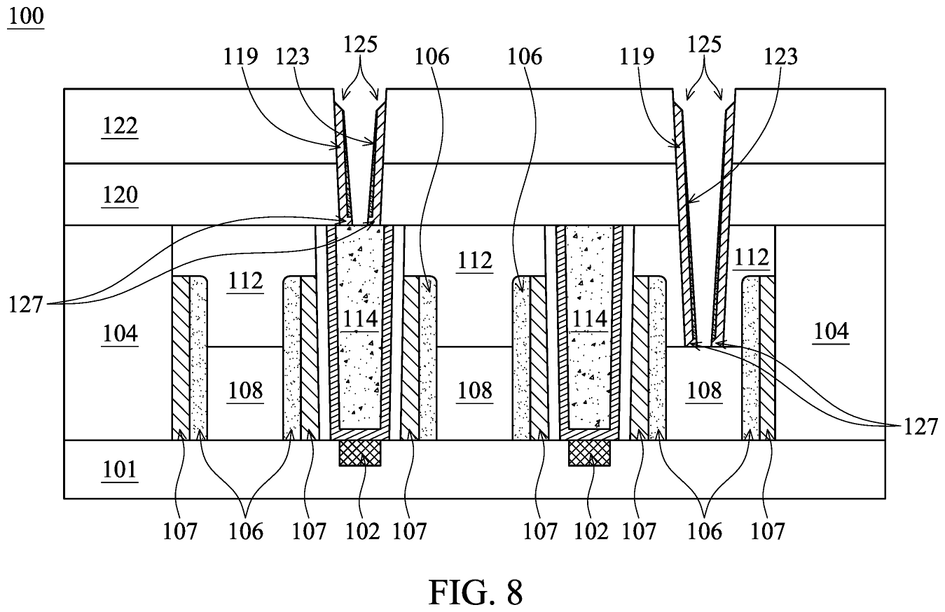

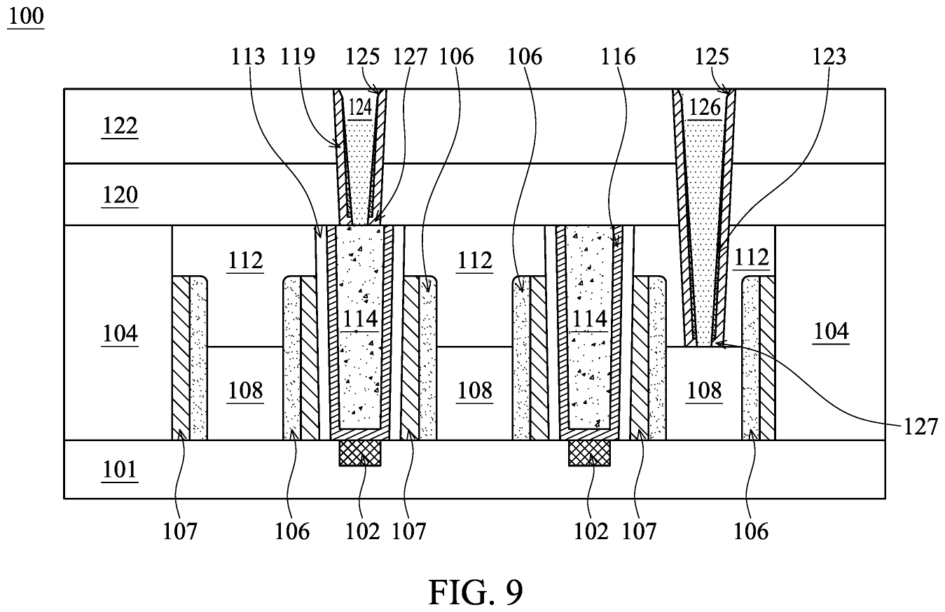

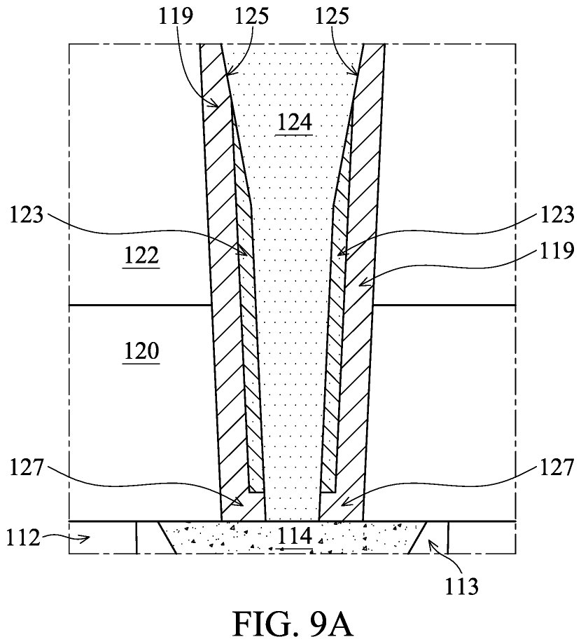

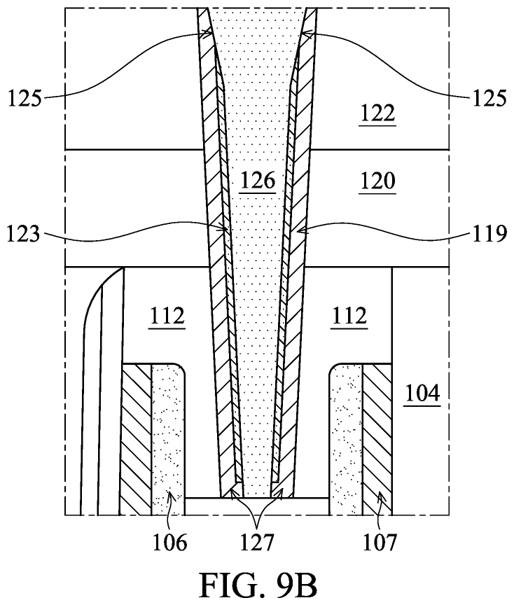

In various embodiments, after the breakthrough etch processes described later below are performed on the liner layer 119, a cross-sectional view of the liner layer 119 reveals a tab 127 that extends from a bottom portion of a sidewall of the gate via and/or the drain via (see also FIGS. 9A and 9B). In some embodiments, the tab 127 extends along a first portion of a horizontal surface of the drain metal layer 114 and/or the gate metal layer 108. In some embodiments, the tab 127 ends with a substantially vertical liner surface disposed within the drain via and/or the gate via. In some embodiments, the substantially vertical liner surface is within 10 degrees of vertical. In some embodiments, the tab 127 prevents the overlying glue layer 123 from contacting the underlying drain metal layer 114 and/or the underlying gate metal layer 108. In various embodiments, the glue layer is not in contact with either the drain metal layer 114 or the gate metal layer 108 because of the tab 127 disposed there-between.

In various embodiments, a glue layer 123 made of a conductive material is next deposited over the liner layer 119. In various embodiments, the glue layer provides the adhesion between drain and gate metals and nearby dielectric layers. If the glue layer were in contact with the underlying gate metal layer 108 or drain metal layer 114 undesirable device performance evolves over time due to degradation of the glue layer 123 caused by electrical operation of the gate and/or drain structures. In some embodiments, the glue layer 123 prevents the underlying gate metal layer 108 and the drain metal layer 114 from being damaged by etching processes during further manufacture of the semiconductor device 100. In some embodiments, the glue layer 123 is disposed over a horizontal surface of the tab 127. In some embodiments, the glue layer 123 ends at a substantially vertical glue surface which is substantially aligned with the substantially vertical liner surface on the tab 127. In some embodiments, the substantially vertical glue surface is within 10 degrees of vertical and is coextensive and continuous with the substantially vertical liner layer. Accordingly, in various embodiments, the glue layer 123 is prevented from contacting the drain metal layer 114 or the gate metal layer 108 by the tab 127 so as to prevent degradation of the glue layer during electrical operation. In various embodiments, the material of the glue layer 123 is at least one of cobalt (Co), ruthenium (Ru), tantalum nitride (TaₓN_{y}) and titanium nitride (TiₓN_{y}).

In various embodiments, a two-step breakthrough etch process is performed on the glue layer 123 disposed over the liner layer 119 in the gate via and the drain via, which results in lowered electrical resistance at the interface of the drain metal layer 114 and the drain via metal layer 124, as well as at the interface of the gate metal layer 108 and the gate via metal layer 126 as later described. In various embodiments, no glue layer 123 remains at the bottom of gate via and the drain via other than the portion disposed over the tab 127. In some embodiments, due to glue layer etching behavior, a thickness of the glue layer 123 at or near the top of VD and VG is thinner than that disposed near the bottom, and is completely removed from some portions of the sidewalls in various embodiments. Due to the double breakthrough etch method, damage to the underlying gate metal layer 108 and drain metal layer 114 is mitigated.

In various embodiments, a drain via metal layer 124 is deposited in a drain via (VD) formed through the first ESL 120 and the second ILD layer 122. In some embodiments, the drain via metal layer 124 is W, Ru, Co, Cu, Mo, TaₓN_{y}, and/or TiₓN_{y}. In some embodiments, a cross-section view of the drain via metal layer 124 is substantially trapezoidal. In other embodiments, a cross-section view of the drain via metal layer 124 is substantially square or rectangular. In some embodiments, a length of the top surface of the drain via metal layer 124 is between about 1 nm and about 80 nm, such as between about 10 nm and about 40 nm. In some embodiments, a length of the top surface of the drain via metal layer 124 is between about 2 nm and about 50 nm, such as between about 10 nm and about 40 nm. In some embodiments, a length of the bottom surface of the drain via metal layer 124 is between about 1 nm and about 80 nm. In some embodiments, a length of the bottom surface of the drain via metal layer 124 is between about 1 nm and about 30 nm, such as between about 15 nm and about 25 nm. In various embodiments, the drain via metal layer 124 forms a low-resistance contact with the underlying portions of the drain structure. In some embodiments, the drain via metal layer 124 is disposed over a second portion of the horizontal surface of the underlying drain metal layer 114, and is further disposed along the substantially vertical liner surface of the tab 127 and the substantially vertical glue surface of the glue layer 123. In some embodiments, the drain via metal layer 124 comprises at least one of copper, tungsten, ruthenium, cobalt and titanium nitride, and substantially fills a remainder of the drain via.

In various embodiments, a gate via metal layer 126 is deposited in a gate via (VG) formed through the first ESL 120 and the second ILD layer 122 by an etching process or the like. In some embodiments, the gate via metal layer 126 is formed from a material such as W, Ru, Co, Cu, Mo, TaₓN_{y} and TiₓN_{y}. In some embodiments, a cross-section of the gate via metal layer 126 is substantially trapezoidal. In other embodiments, the gate via metal layer 126 is substantially square, rectangular or triangular. In various embodiments, the gate via metal layer 126 is deposited by CVD, PVD, ALD, or FCVD. In some embodiments, the length of the top surface of the gate via metal layer 126 is between about 1 nm and about 50 nm, such as between about 10 nm and about 30 nm. In some embodiments, the length of the top surface of the gate via metal layer 126 is between about 2 nm and about 20 nm, such as between about 5 nm and about 15 nm. In some embodiments, the length of the bottom surface of the gate via metal layer 126 is between about 1 nm and about 50 nm, such as between about 5 nm and about 15 nm. In some embodiments, the length of the bottom surface of the gate via metal layer 126 is between about 1 nm and about 19 nm, such as between about 5 nm and about 15 nm. In some embodiments, the gate via metal layer 126 comprises at least one of copper, tungsten, ruthenium, cobalt and titanium nitride and substantially fills a remainder of the gate via.

In various embodiments, the top ends of the glue layer 123 and the liner layer 119 are tapered ends 125, which are formed as a result of the two-step breakthrough method discussed below, and which lowers an interface resistance of the drain via metal layer 124 and the gate via metal layer 126. In some embodiments, the tapered end 125 of the glue layer 123 is between about 0.1 nm and about 5 nm from the top surfaces of the sidewalls. In some embodiments, the tapered end 125 of the glue layer 123 and the tapered end 125 of the liner layer 119 are substantially continuous. In some embodiments, the tapered ends 125 are rounded or are aligned to form a continuous angled flat surface.

In various embodiments, the gate via metal layer 126 forms a low-resistance contact with the underlying gate structure. In various alternate embodiments, the drain and one or more gates are shorted (i.e., connected to the same voltage drop in the semiconductor device 100) according to design requirements. In some such embodiments, the drain and a gate are connected to avoid electrical interference with one or more other gate structures. In other embodiments, the drain and gates are each connected to separate signal lines of the semiconductor device 100. In some embodiments, the gate via metal layer 126 is deposited for multiple gates, such as in a FinFET device. In various embodiments, the drain via metal layer 124 and the gate via metal layer 126 are composed of the same metals. In other embodiments, one or more of the drain via metal layer 124 and the gate via metal layer 126 are composed of the different metals. In some embodiments, a top surface of the gate via metal layer 126, the drain via metal layer 124 and the second ILD layer 122 are smoothed or planarized, such as by CMP, to form a substantially smooth continuous top surface of the completed semiconductor device 100.

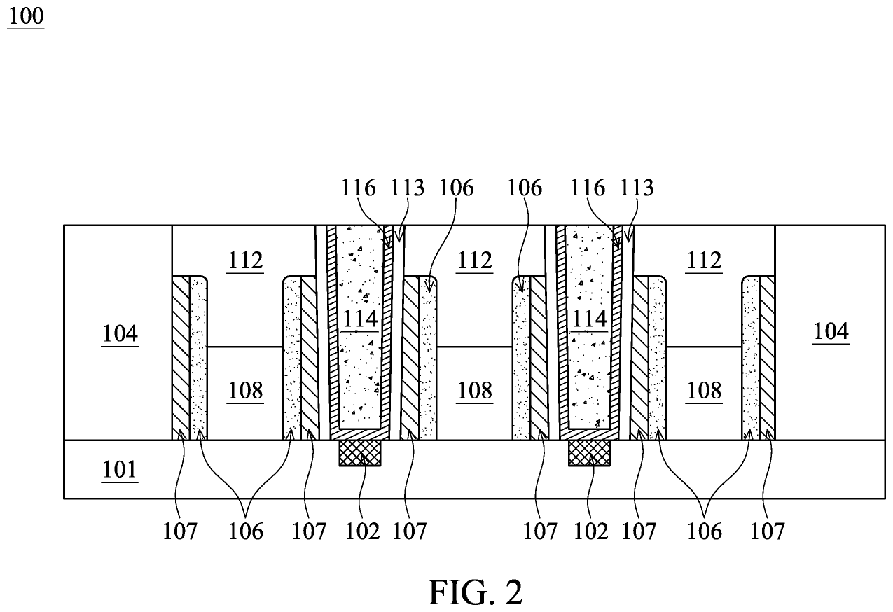

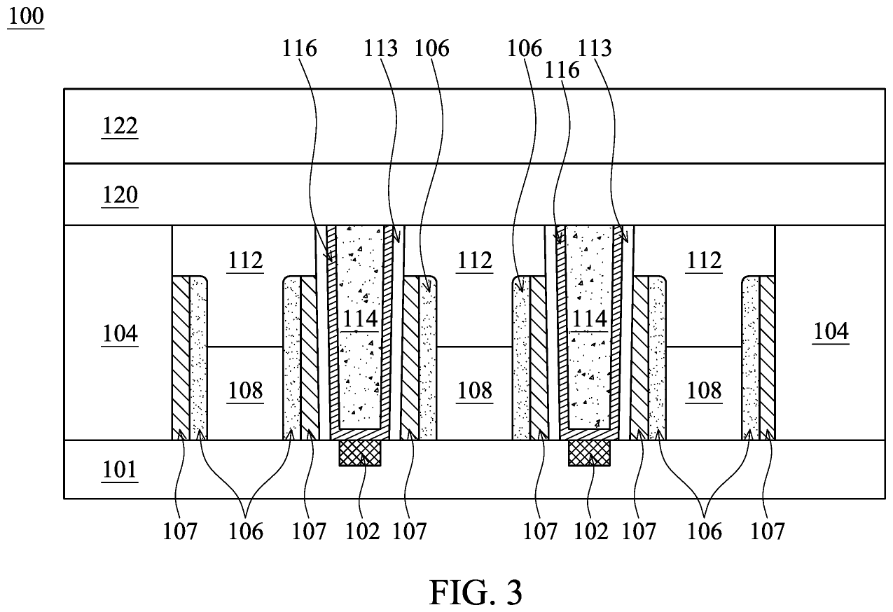

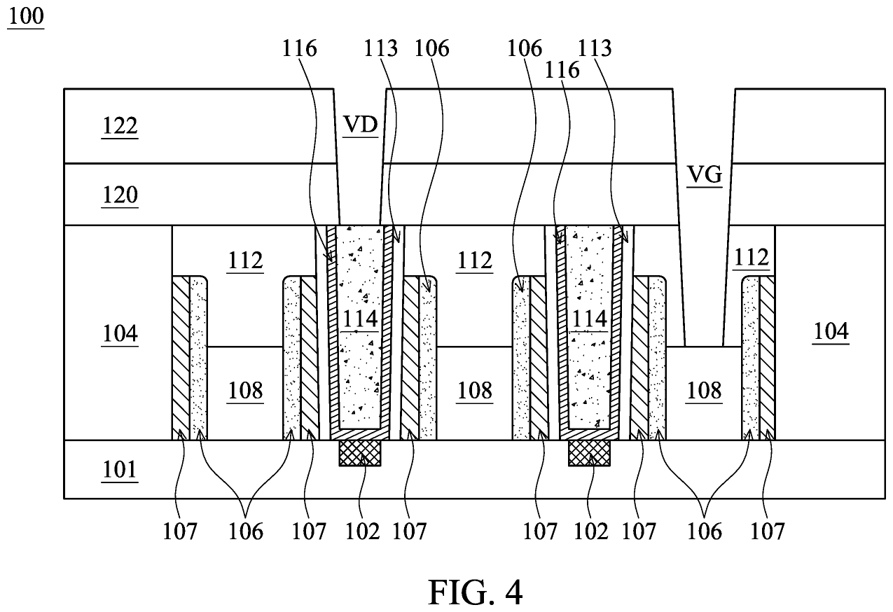

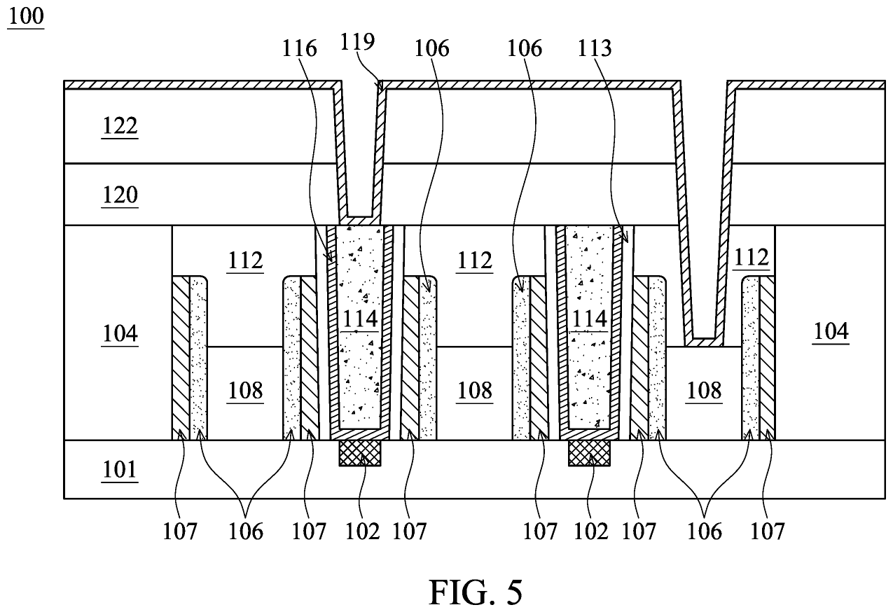

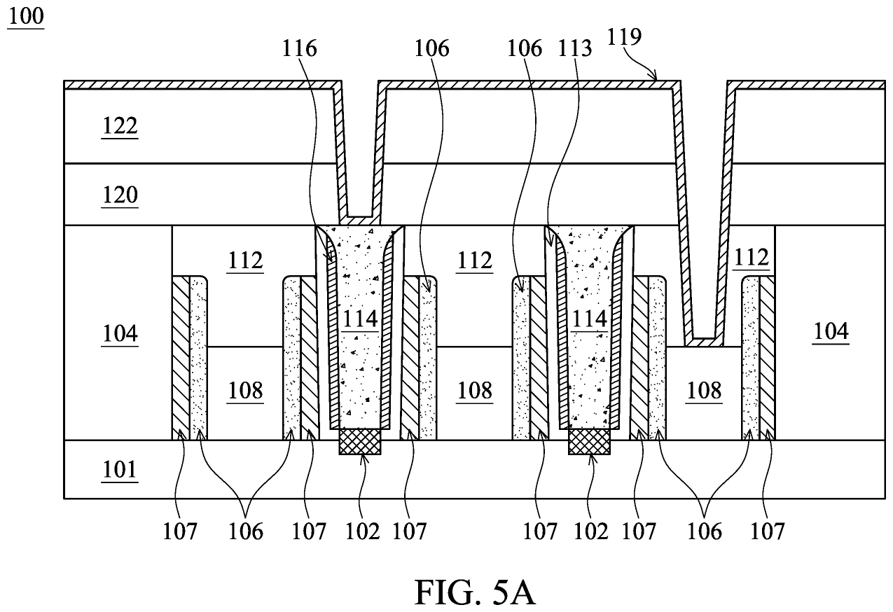

FIG. 2, FIG. 3, FIG. 4, FIG. 5, FIG. 5A, FIG. 6, FIG. 7, FIG. 8 and FIG. 9 show cross sectional views of various stages of the sequential fabrication process of a semiconductor device 100 according to various embodiments. It is understood that additional operations can be provided before, during, and after processes shown by FIGS. 2-9, and some of the operations described below can be replaced or eliminated, for additional embodiments of the method. The order of the operations/processes may be interchangeable.

FIG. 2 illustrates portions of the semiconductor device 100 that are completed, in various embodiments, in a front end of line (FEOL) process. These portions include the gate structures having the first spacer 106, the second spacer 107, the gate metal layer 108 and the gate helmet layer 112, as previously described. In various embodiments, a drain structure having the drain liner layer 113, the drain glue layer 116 and the drain metal 114 is formed between two or more adjacent gate structures. In some embodiments, the drain structure is formed over an exposed portion of the underlying silicide layer 102. CMP or other planarization techniques are performed in various embodiments to smooth the tops surfaces of the gate structures, the drain structures and the intervening dielectric layer 104.

FIG. 2 further illustrates the results of a deposition of materials to form the drain structures over the silicide layers 102, in various embodiments. In some embodiments, the drain metal layer 114 is deposited over top surface of the portion of the drain glue layer 116 that is, in turn, disposed over the silicide layer 102 and between the drain liner layers 113, thereby forming a drain structure. In various embodiments, the material of the drain metal layer 114 is deposited by PVD at a temperature between about 10 degrees and about 400 degrees Celcius (C) and at a pressure between about 0.1 millitorr (mtorr) and about 1 torr. In other embodiments, the drain metal material is deposited by CVD or ALD.

FIG. 2 further illustrates the results of an etching back of the material used to form the drain metal layer 114 in various embodiments. This operation is performed by dry etch back or wet etch back processes, in various embodiments to smooth the material before further manufacturing operations are performed, such as by CMP or other smoothing and planarization techniques.

FIG. 3 illustrates the results, in various embodiments, of the deposition of the first ESL 120 and the second ILD layer 122. In various embodiments, the first ESL 120 is first deposited over the gate and drain structures and the dielectric layer 104 completed above. In some embodiments, a CMP or like smoothing/planarization is then performed in some embodiments to smooth a top surface of the first ESL 120. In various embodiments, the second ILD layer 122 is then deposited on the top surf ace of the first ESL 120.

FIG. 4 illustrates the results, in various embodiments, of the etching of the first ESL 120 and second ILD layer 122 to form gate vias (VG) and drain vias (VD), respectively, over the desired drain structures and the desired gate structures, in accordance with design requirements. In various embodiments, the drain via (VD) is formed over the left drain structure as shown in FIG. 4. In other embodiments, the right drain structure may be used alternatively or in addition thereto. In various embodiments, the gate via is formed over the rightmost gate structure. In other embodiments, one or both of the remaining gate structures may be selected, alternatively or in addition thereto.

FIG. 5 illustrates the results of a follow-on deposition of a liner layer 119 in various embodiments. In some embodiments, the liner layer 119 is disposed over the top surface of the second ILD layer 122. In some embodiments, the liner layer 119 is disposed along the sidewalls of the VD and the VG. In some embodiments, the liner layer is further disposed over the exposed portions of the drain metal layer 114 and the gate metal layer 108 in the drain via and the gate via, respectively.

FIG. 5A illustrates the results of a follow-on deposition of a liner layer 119 in an alternative embodiment where drain liner layer 113 and drain glue layer 116 are tapered at the top ends thereof within the drain structure, similar to the tapered ends 125. In some embodiments, the drain metal layer 114 is in contact with the drain liner layer 113 at the top portion thereof.

FIG. 6 illustrates the results of a follow-on deposition of the glue layer 123 over the liner layer 119 in various embodiments and as previously described above. In various embodiments, the glue layer 123 is coextensive with the liner layer 119 after deposition.

FIG. 7 illustrates the results of a first breakthrough etch of the glue layer 123 in various embodiments. In some embodiments, the first breakthrough etch of the glue layer 123 exposes an underlying portion of the liner layer 119 within both the drain via and the gate via at the bottom thereof. In some embodiments, the first breakthrough etch removes the horizontal portions of the glue layer 123 disposed above the top surface of the second ILD layer 122. In some embodiments, the ends of the glue layer 123 disposed near a top of the VD and the VG are tapered as a result of the first breakthrough etch process. In some such embodiments, the tapered ends 125 are rounded.

In some embodiments, the first breakthrough process is plasma etching. In various embodiments, the conditions used for the first breakthrough process are as follows: (i) Chlorine (Cl) gas is used alone or in combination with gaseous O₂ in various embodiments. In some embodiments, a ratio of Cl to O₂ is between 3 to 1 and 10 to 1. (ii) In some embodiments, the inductively coupled plasma (ICP) power used is between 10 and 1000 watts. (iii) In some embodiments, the pressure used is between about 5 mtorr and about 75 mtorr. (iv) In some embodiments, the bias voltage used is between about 10 volts and about 120 volts. In some embodiments, Argon (Ar) bombardment is employed. (v) In some embodiments, a high selectivity to the VG/VD metal is employed (for example, greater than about 5:1).

FIG. 8 illustrates the results of a second breakthrough etch of the via liner layer 119. In some embodiments, the second breakthrough etch is performed immediately after the first breakthrough etch without any intervening operation performed during the manufacturing process. In some embodiments, the first and second breakthrough operations are performed consecutively as a two-step breakthrough process, for example, within the same process chamber. In various embodiments, the conditions of the second breakthrough process are as follows: (i) Fluorine (F) gas, such as CHₓF_{y} is employed. (ii) In some embodiments, the ICP power used is between about 10 watts and about 1000 watts. (iii) In some embodiments, the pressure used is between about 5 mtorr and about 70 mtorr. (iv) In some embodiments, the bias voltage used is between about 10 volts and about 120 volts. In some embodiments, Ar bombardment is employed. (v) In some embodiments, post treatment is applied with gaseous H₂ or H₂/N₂ or He. (vi) In some embodiments, a high selectivity to the drain metal layer 114 and the gate metal layer 108 is employed (for example, greater than about 10:1).

In some embodiments, the second breakthrough additionally tapers the ends of the glue layer 123 and the liner layer 119 near the top of the drain via and the gate via. In some embodiments, as a result of the second breakthrough, the tabs 127 are formed are formed within the VD and VG.

FIG. 9 illustrates a deposition of the drain via metal layer 124 and the gate via metal layer 126, in the drain via and the gate via, respectively, in some embodiments. In various embodiments, these depositions are followed by CMP (or other planarization or smoothing) of the top surface of the drain via metal layer 124, the gate via metal layer 126 and the second ILD layer 122, thereby forming a completed semiconductor device 100.

FIG. 9A illustrates a detailed view of the drain via formed over a drain structure according to some embodiments. In some embodiments, the top ends of the liner layer 119 and the glue layer 123 are tapered to form tapered ends 125 as a result of the breakthrough etching operations. In some embodiments, the tabs 127 are formed as a result of the breakthrough etching operations, which prevents the glue layer 123 from reaching the exposed portions of the drain metal layer 114. In some embodiments, the drain via metal layer 124 fills a remainder of the VD and contacts the exposed portion of the drain metal layer 114, as well as the substantially vertical liner surface of the liner layer 119 and the substantially vertical glue surface the glue layer 119 that form the tab 127. In some embodiments, the drain via metal layer 124 is in contact with the liner layer 119 at the top (tapered end) thereof.

FIG. 9B illustrates a detailed view of the VG formed over a gate structure according to some embodiments. In some embodiments, the top ends of the liner layer 119 and the glue layer 123 are tapered to form tapered ends 125 as a result of previous breakthrough operations. In some embodiments, the tabs 127 prevent the glue layer 123 from reaching the exposed portions of the gate metal layer 108. In some embodiments, the gate via metal layer 126 fills a remainder of the VG and contacts the exposed portion of the gate metal layer 108, as well as along the substantially vertical liner surface of the liner layer 119 and the substantially vertical glue surface the glue layer 119 that form the tab 127. In some embodiments, the gate via metal layer 126 is in contact with the liner layer 119 at the top (tapered end) thereof.

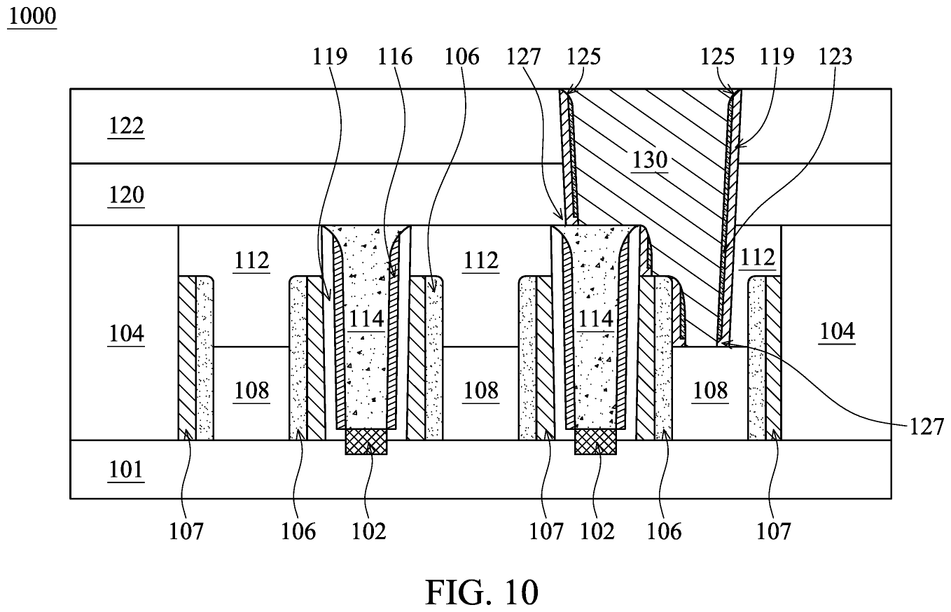

FIG. 10 illustrates an alternate embodiment of a semiconductor device 1000 having a shorted drain via and gate via, in accordance with design requirements. Any one or more of the gate or drain structures shown in FIG. 10 could be shorted in this manner in various embodiments. In some embodiments, the shorted drain and gate vias are formed by first performing an etching process to form an etched portion of the drain via metal layer 124 and an etched portion of an adjoining or nearby gate via metal layer 126. In such embodiments, a gate-drain metal layer 130 is deposited over and completely fills the etched portion of the drain via metal and the etched portion of the gate via metal. In some embodiments, the gate-drain metal layer 130 is formed of the same materials as either the drain via metal layer 124 or the gate via metal layer 126. In various embodiments, a CMP process, or other smoothing or planarization, may finally be performed on the top surfaces of the second ILD layer 122 and the gate-drain metal layer 130 to form a completed semiconductor device 1000.

Aspects of some embodiments herein can be applied to FEOL, middle end of the line (MEOL) and back end of line (BEOL) processes. For example, replacement drain structures or stacks are formed in a similar manner according to some embodiments. Regarding replacement gate stacks, for example, conformal layers, such as a dielectric layer and/or work-function tuning layer(s), which are formed where a dummy gate stack is removed, can be deposited. In other examples, aspects of the foregoing can be incorporated in conductive features formed in intermetallization dielectrics (IMDs) in BEOL processing. The methods and structures disclosed herein are useful for a wide variety of semiconductor process manufacturing, packaging, and assembly as well as by etching and plating tool vendors and suppliers. The methods and structures herein are particularly useful in advanced FinFET processes, including WLP/InFO (wafer level packaging/integrated fan-out).

This disclosure introduces methods and resulting structures employing a consecutive two-step breakthrough process of the glue layer and liner to from a protective tab of the liner protruding between a bottom end of the glue layer and an underlying gate or drain metal layer. This protects the glue layer from degradation over time within the formed gate or drain contacts, and protects the underlying gate and drain metal layers during manufacture. A top end of the glue layers and liner layers may be tapered prior to via metal deposition, which results in improved device performance due to reduced resistance. The disclosed process may be used in the formation of semiconductor structures other than the gate and drain structures as described herein.

According to various embodiments, a semiconductor structure includes a liner layer made of an insulating material and having a tab that extends from a sidewall of a via along a first portion of a horizontal surface of a metal layer. In various embodiments, the tab ends with a substantially vertical liner surface. In various embodiments, a glue layer is made of a conductive material and disposed over a horizontal surface of the tab. In various embodiments, the glue layer ends at a substantially vertical glue surface aligned with the substantially vertical liner surface, wherein the glue layer is prevented from contacting the metal layer by the tab so as to prevent degradation of the glue layer during electrical operation. In some embodiments, the semiconductor structure further has a via metal disposed over a second portion of the horizontal surface of the metal layer and along the substantially vertical liner surface and the substantially vertical glue surface of the tab. In some embodiments, the liner layer is disposed along the sidewall of the via and has a tapered end at a top of the sidewall. In some embodiments, the glue layer is disposed over at least a portion of the liner layer along the sidewall and has a tapered end toward a top of the sidewall. In some embodiments, the tapered end of the glue layer is between about 0.1 nm and about 5 nm from the top of the sidewall. In some embodiments, the tapered end of the glue layer and the tapered end of the liner layer are substantially continuous. In some embodiments, the liner layer is one or more of SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZrₓO_{y}, SiₓO_{y}C_{z}, HfₓO_{y}, LaₓO_{y}, AlₓO_{y}, Si_{w}OₓC_{y}N_{z}, AlₓO_{y}N_{z}, YₓO_{y}, or TaₓC_{y}N_{z}, and the liner layer has a thickness of between about 1 nm and about 30 nm. In some embodiments, the glue layer is made of one or more of cobalt, ruthenium, tantalum nitride or titanium nitride, wherein the glue layer comprises a maximum thickness of between about 0.5 nm and about 3 nm. In some embodiments, the via comprises a drain via that extends through at least one etch stop layer to reach the horizontal surface of the metal layer. In some embodiments, the metal layer is disposed over a silicide layer that extends above of top surface of a substrate. In some embodiments, the metal layer is disposed within a drain glue layer and a drain liner layer within a drain metal structure, and a top end of the drain glue layer and a top end of the drain liner layer are tapered. In some embodiments, the via comprises a gate via that extends through at least one etch stop layer and a gate helmet layer to reach the horizontal surface of the metal layer. In some embodiments, the sidewall is within 20 degrees of vertical.

According to various embodiments, a method for forming a semiconductor device structure includes: (i) etching a via through at least one etch stop layer to expose a horizontal surface of a metal layer, the via having a sidewall; (ii) performing a first deposition process to form a liner layer made of an insulating material along the sidewall and over the horizontal surface of the metal layer; (iii) performing a second deposition process to form a glue layer made of a conductive material over the liner layer; (iv) performing a first breakthrough of the glue layer to expose an underlying portion of the liner layer; and (v) immediately after the first breakthrough, performing a second breakthrough of the underlying portion of the liner layer to expose an underlying portion of the metal layer, thereby forming a tab that prevents the overlying glue layer from contacting the underlying metal layer. In some embodiments, the second breakthrough additionally tapers an end of the glue layer and an end of the liner layer near the top of the via. In some embodiments, the end of the glue layer and the end of the liner layer are tapered to form a continuous angled surface. In some embodiments, the first breakthrough uses a chlorine gas and the second breakthrough uses a fluorine gas.

According to various embodiments, a method of manufacturing a semiconductor device, includes (i) etching a drain via through at least one etch stop layer to expose a horizontal surface of a drain metal layer, the drain via having a sidewall; (ii) etching a gate via through at least one etch stop layer and a gate helmet layer to expose a horizontal surface of a gate metal layer, the gate via having a sidewall; (iii) depositing a liner layer made of an insulating material along the sidewall of the drain via, over the horizontal surface of the drain metal layer, along a sidewall of the gate via, and over the horizontal surface of the gate metal layer; (iv) depositing a glue layer made of a conductive material over the liner layer; (v) performing a first breakthrough etch of the glue layer to expose an underlying portion of the liner layer within the drain via and the gate via; and (vi) immediately after the first breakthrough etch, performing a second breakthrough etch of the underlying portion of the liner layer to expose underlying portions of the drain metal layer and the gate metal layer, wherein the glue layer is not in contact with either the drain metal layer or the gate metal layer. In some embodiments, a first deposition process is performed to form a drain via metal layer over the glue layer and the exposed portion of the drain metal layer, wherein the drain via metal layer substantially fills the drain via, and a second deposition process is performed to form a gate via metal layer over the glue layer and the exposed portion of the gate metal layer, wherein the gate via metal layer substantially fills the gate via. In some embodiments, an etching process is performed to form an etched portion of the drain via metal layer connected with an etched portion of the gate via metal layer and a via metal layer is deposited over the etched portion of the drain via metal and the etched portion of the gate via metal. In some embodiments, the second breakthrough etch tapers top ends of the glue layer and the liner layer towards of a top of the gate via and the drain via.

The foregoing outlines features of several embodiments or examples so that those skilled in the art better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a liner layer made of an insulating material and having a tab that extends from a sidewall of a via along a first portion of a horizontal surface of a metal layer, the tab ending at a substantially vertical liner surface; and
a glue layer made of a conductive material and disposed over a horizontal surface of the tab, the glue layer ending at a substantially vertical glue surface aligned with the substantially vertical liner surface, wherein the glue layer is prevented from contacting the metal layer by the tab so as to prevent degradation of the glue layer during electrical operation.

2. The semiconductor structure of claim 1, further comprising a via metal disposed over a second portion of the horizontal surface of the metal layer and further disposed along the substantially vertical liner surface and the substantially vertical glue surface of the tab.

3. The semiconductor structure of claim 1, wherein the liner layer is disposed along the sidewall of the via and has a tapered end at a top of the sidewall, and wherein the glue layer is disposed over at least a portion of the liner layer along the sidewall and has a tapered end toward a top of the sidewall.

4. The semiconductor structure of claim 3, wherein the tapered end of the glue layer is between about 0.1 nanometers (nm) and about 5 nm from the top of the sidewall.

5. The semiconductor structure of claim 3, wherein the tapered end of the glue layer and the tapered end of the liner layer are substantially continuous.

6. The semiconductor structure of claim 1, the liner layer comprising at least one of SiₓN_{y}, ZrₓSi_{y}, SiₓC_{y}N_{z}, ZrₓAl_{y}O_{z}, TiₓO_{y}, TaₓO_{y}, ZrₓO_{y}, LaₓO_{y}, ZrₓN_{y}, SiₓC_{y}, ZnₓO_{y}, SiₓO_{y}C_{z}, HfₓO_{y}, LaₓO_{y}, AlₓO_{y}, Si_{w}OₓC_{y}N_{z}, AlₓO_{y}N_{z}, YₓO_{y}, and TaₓC_{y}N_{z}, wherein the liner layer comprises a thickness of between about 1 nm and about 30 nm.

7. The semiconductor structure of claim 1, the glue layer comprising at least one of cobalt, ruthenium, tantalum nitride and titanium nitride, wherein the glue layer comprises a maximum thickness of between about 0.5 nm and about 3 nm.

8. The semiconductor structure of claim 1, wherein the via comprises a drain via that extends through at least one etch stop layer to reach the horizontal surface of the metal layer.

9. The semiconductor structure of claim 8, wherein the metal layer is disposed over a silicide layer that extends above of top surface of a substrate.

10. The semiconductor structure of claim 8, wherein the metal layer is disposed within a drain glue layer and a drain liner layer within a drain metal structure, and a top end of the drain glue layer and a top end of the drain liner layer are tapered.

11. The semiconductor structure of claim 1, wherein the via comprises a gate via that extends through at least one etch stop layer and a gate helmet layer to reach the horizontal surface of the metal layer.

12. The semiconductor structure of claim 1, wherein the sidewall is within 20 degrees of vertical.

13. A method for forming a semiconductor device structure, comprising:
etching a via through at least one etch stop layer to expose a horizontal surface of a metal layer, the via having a sidewall;
performing a first deposition process to form a liner layer made of an insulating material along the sidewall and over the horizontal surface of the metal layer;
performing a second deposition process to form a glue layer made of a conductive material over the liner layer;
performing a first breakthrough of the glue layer to expose an underlying portion of the liner layer; and
immediately after the first breakthrough, performing a second breakthrough of the underlying portion of the liner layer to expose an underlying portion of the metal layer, thereby forming a tab that prevents the overlying glue layer from contacting the underlying metal layer.

14. The method of claim 13, wherein the second breakthrough additionally tapers an end of the glue layer and an end of the liner layer near the top of the via.

15. The method of claim 14, wherein the end of the glue layer and the end of the liner layer are tapered to form a continuous angled surface.

16. The method of claim 13, wherein the first breakthrough uses a chlorine gas and the second breakthrough uses a fluorine gas.

17. A method of manufacturing a semiconductor device, comprising:
etching a drain via through at least one etch stop layer to expose a horizontal surface of a drain metal layer, the drain via having a sidewall;
etching a gate via through at least one etch stop layer and a gate helmet layer to expose a horizontal surface of a gate metal layer, the gate via having a sidewall;
depositing a liner layer made of an insulating material along the sidewall of the drain via, over the horizontal surface of the drain metal layer, along a sidewall of the gate via, and over the horizontal surface of the gate metal layer;
depositing a glue layer made of a conductive material over the liner layer;
performing a first breakthrough etch of the glue layer to expose an underlying portion of the liner layer within the drain via and the gate via; and
immediately after the first breakthrough etch, performing a second breakthrough etch of the underlying portion of the liner layer to expose underlying portions of the drain metal layer and the gate metal layer, wherein the glue layer is not in contact with either the drain metal layer or the gate metal layer.

18. The method of claim 17, further comprising:
performing a first deposition process to form a drain via metal layer over the glue layer and the exposed portion of the drain metal layer, wherein the drain via metal layer substantially fills the drain via; and
performing a second deposition process to form a gate via metal layer over the glue layer and the exposed portion of the gate metal layer, wherein the gate via metal layer substantially fills the gate via.

19. The method of claim 17, further comprising:
performing an etching process to form an etched portion of the drain via metal layer connected with an etched portion of the gate via metal layer; and
depositing a via metal layer over the etched portion of the drain via metal and the etched portion of the gate via metal.

20. The method of claim 17, wherein the second breakthrough etch tapers top ends of the glue layer and the liner layer towards of a top of the gate via and the drain via.
